(19) United States
(12) Patent Application Publication
(10) Pub. No.: US 2018/0223181 A1
(43) Pub. Date: Aug. 9, 2018

(54) SILOXANE MONOMER, POLYMER THEREOF, COMPOSITION CONTAINING SAID POLYMER, AND ELECTRONIC ELEMENT

(71) Applicant: DIC Corporation, Tokyo (JP)

(72) Inventors: Yuusaku GOTOU, Chiba (JP); Eiji OTSUKI, Chiba (JP)

(21) Appl. No.: 15/772,003

(22) PCT Filed: Oct. 27, 2016
(86) PCT No.: PCT/JP2016/081840

§ 371 Date: Apr. 27, 2018

(30) Foreign Application Priority Data
Oct. 29, 2015 (JP) 2015-212956

(51) Int. Cl. C09K 11/02; C08F 30/08; C09K 11/06; C07F 7/08; C09D 143/04; C09D 5/22; C09D 5/24; H01L 51/00

(52) U.S. Cl. CPC C09K 11/025; C08F 30/08; C09K 11/06; C07F 7/0849; C08G 77/70; C09D 5/22; C09D 5/24; H01L 51/0094; H01L 51/0085; C09D 143/04

(57) ABSTRACT

An object of the present invention is to provide a polymer obtained from novel monomers, a composition containing the polymer, an electronic material composition, and an electronic element, the polymer, by being added to the electronic material composition or ink applied for coating film formation, improving the smoothness (leveling property) of a coating film to be obtained without deteriorating a driving stability of the electronic element. With the novel siloxane monomers, the polymer thereof, the composition containing the polymer, and the electronic material composition according to the present invention, it is possible to produce a smooth organic thin film. The electronic element including either of these compositions has a prolonged element lifetime and improved driving stability.

### TECHNICAL FIELD

The present invention relates to siloxane monomers, a polymer thereof, a composition containing the polymer, an electronic material composition, and an electronic element containing the electronic material composition.

### BACKGROUND ART

In recent years, researches on electronic elements such as TFTs, solar cells, and organic electroluminescence elements have been conducted in various ways. In the related art, these electronic elements have been prepared by vacuum film formation, but in recent years, due to the demand on increasing the area of the substrate and reducing the cost of the product, attention has been paid to methods of preparing electronic elements by printing.

These electronic elements can be roughly classified into a low molecular weight material and a high molecular weight material on the basis of the forming materials.

Regarding the low molecular weight electronic material, in addition to the vacuum film formation, which has been used in the related art, research and development of techniques for forming a film containing an electronic material by using various coating methods such as inkjet, nozzle jet, flexographic printing, and transfer method have been carried out recently. On the other hand, since vacuum film formation is not suitable for the high molecular weight electronic material due to the large molecular weight, the above-mentioned coating method is mainly used as in the low molecular weight material.

Since the semiconductor film obtained through coating film formation is inferior in smoothness compared to that obtained through the vacuum film formation, and exhibits deteriorated electronic element characteristics, a leveling agent for forming an organic semiconductor-containing layer, with which a semiconductor-containing layer with excellent flatness for an electronic element can be formed, and a method of using the same, a composition and ink for forming an organic semiconductor-containing layer, and an organic device and a method of producing the same have been studied, and for example, PTL 1 discloses a leveling agent for forming an organic semiconductor-containing layer containing one or both of a siloxane compound having a specific structure and a (meth)acrylic polymer.

### CITATION LIST

### Patent Literature

[PTL 1] JP-A-2014-205830

### SUMMARY OF INVENTION

### Technical Problem

For the leveling effect, the coating film obtainable according to the invention described in PTL 1 may exhibit a certain degree of flatness, but it cannot be said that a sufficient flatness of the coating film is ensured from the viewpoint of achieving high performance organic light emitting element. Furthermore, since the (meth)acrylic polymer includes a carbonyl group, which serves as a charge trap site in an electronic element, driving stability such as luminous efficiency or lifetime of the electronic element may be deteriorated. As a result, an electronic element not exhibiting a desired performance may be obtained.

In view of the above, an object of the present invention is to provide a polymer obtained from novel monomers which is added to an electronic material composition or ink to be applied for formation of a coating film in order to improve the smoothness (leveling property) of the coating film without deteriorating the driving stability of an electronic element, a composition containing the polymer, an electronic material composition, and an electronic element.

### Solution to Problem

As a result of an extensive research to solve the above problems, the inventors of the present invention have found that it is possible to produce a smooth organic thin film using a polymer obtained from novel monomers of the present invention, a composition containing the polymer, and an electronic material composition, and have found that the an electronic element containing these compositions exhibits improved driving stability, thereby completing the present invention.

That is, the present invention relates to novel monomers, a polymer thereof, a composition and an electronic material composition containing the polymer, and an electronic element containing the electronic material composition.

Provided are:

monomers represented by general formula (1);

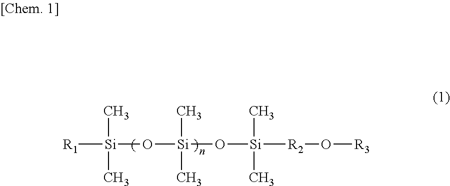

(In general formula (1), n represents 1 to 1,000, R₁ and R₂ represent a hydrocarbon group which may include an ether bond, and R₃ represents a vinyl group or an organic group including a vinyl group, provided that the organic group does not include a carbonyl group in the structure.)

a polymer obtained by polymerizing at least a monomer selected from the monomers represented by general formula (1);

a polymer obtained by copolymerizing at least a monomer selected from the monomers represented by general formula (1) and a monomer other than the monomers represented by general formula (1);

a composition containing the polymer;

an electronic material composition containing the polymer; and

an electronic element containing the composition or the electronic material composition.

### Advantageous Effects of Invention

According to the present invention, it has been found that a smooth organic thin film can be produced using the composition containing the polymer obtained from the novel monomers of the present invention, and that the electronic element obtained from the organic thin films exhibits improved driving stability such as luminous efficiency or lifetime.

### DESCRIPTION OF EMBODIMENTS

Embodiments of the present invention will be described in detail below.

[Siloxane Monomers]

Siloxane monomers of the present invention are represented by following general formula (1):

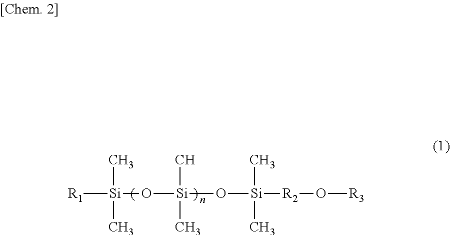

(In general formula (1), n represents 1 to 1,000, R₁ and R₂ represent a hydrocarbon group which may include an ether bond, and R₃ represents a vinyl group or an organic group including a vinyl group, provided that the organic group does not include carbonyl group in the structure.)

There is no particular limitation on R₁; examples thereof include a C1 to C10 alkyl group, a C2 to C10 alkoxyalkyl group, a C3 to C30 cycloalkyl group, a C4 to C30 cycloalkoxyalkyl group, a C6 to C20 aryl group, and a C6 to C20 aryloxy group.

There is no particular limitation on the C1 to C10 alkyl group; examples thereof include a methyl group, an ethyl group, a propyl group, an isopropyl group, a butyl group, an iso-butyl group, a sec-butyl group, a tert-butyl group, a pentyl group, a hexyl group, and a decyl group.

There is no particular limitation on the C2 to C10 alkoxyalkyl group; examples thereof include a methoxymethyl group, a methoxyethyl group, an ethoxyethyl group, a propoxyethyl group, a propoxypropyl group, a butoxypropyl group, a butoxybutyl group, a butoxypentyl group, and a pentyloxypentyl group.

There is no particular limitation on the C3 to C30 cycloalkyl group; examples thereof include a cyclopropyl group, a cyclobutyl group, a cyclopentyl group, a cyclohexyl group, a cycloheptyl group, a tricyclo[5,2,1,0 (2,6)]decyl group, and an adamantyl group, and the cycloalkyl group preferably includes 3 to 18 carbon atoms.

There is no particular limitation on the C4 to C30 cycloalkoxyalkyl group; examples thereof include a cyclopropyloxymethyl group, a cyclobutyloxyethyl group, a cyclopentyloxypropyl group, a cyclohexyloxypropyl group, a cycloheptyloxypropyl group, a tricyclo[5,2,1,0(2,6)]decyloxypropyl group, and an adamantyloxypropyl group, and the cycloalkoxyalkyl group preferably includes 3 to 18 carbon atoms.

Examples of the C6 to C20 aryl group include a phenyl group, a naphthyl group, an anthracenyl group, and a biphenyl group.

Examples of the C6 to C20 aryloxy group include a phenyloxy group, a naphthyloxy group, an anthracenyloxy group, and a biphenyloxy group.

In this case, at least one of hydrogen atoms that constitute the C1 to C10 alkyl group, the C1 to C10 alkoxyalkyl group, the C3 to C30 cycloalkyl group, the C3 to C30 cycloalkoxyalkyl group, the C6 to C20 aryl group, or the C6 to C20 aryloxy group may be substituted with the C1 to C10 alkyl group.

Among them, R₁ is preferably the C1 to C10 alkyl group from the viewpoint of enhancing the leveling property, more preferably a methyl group, an ethyl group, a propyl group, an isopropyl group, a butyl group, an iso-butyl group, a sec-butyl group, or a tert-butyl group from the viewpoint of increasing compatibility with a solvent, and even more preferably a methyl group, an ethyl group, a propyl group, or a butyl group from the viewpoint of improving the electronic element characteristics.

There is no particular limitation on R₂; examples thereof include a C1 to C10 alkylene group, a C2 to C10 alkyleneoxyalkylene group, a C3 to C30 cycloalkylene group, a C4 to C30 cycloalkyleneoxyalkylene group, a C6 to C20 arylene group, and a C7 to C20 aryleneoxyalkylene group.

There is no particular limitation on the C1 to C10 alkylene group; examples thereof include a methylene group, an ethylene group, a propylene group, an isopropylene group, a butylene group, an iso-butylene group, a pentylene group, a hexylene group, and a decylene group.

There is no particular limitation on the C2 to C10 alkyleneoxyalkylene group; examples thereof include a methyleneoxymethylene group, an ethyleneoxymethylene group, a propyleneoxyethylene group, a propyleneoxypropylene group, propyleneoxybutylene group, a butyleneoxybutylene group, a butyleneoxypentylene group, and a pentyleneoxypentylene group.

There is no particular limitation on the C3 to C30 cycloalkylene group; examples thereof include a cyclopropylene group, a cyclobutylene group, a cyclopentylene group, a cyclohexylene group, and a cycloheptylene group, the cycloalkylene group preferably includes 3 to 10 carbon atoms.

There is no particular limitation on the C4 to C30 cycloalkyleneoxyalkyl group; examples thereof include a cyclopropyleneoxyethylene group, a cyclobutyleneoxypropylene group, a cyclopentyleneoxypropylene group, a cyclohexyleneoxypropylene group, and a cycloheptylene oxypropylene group, and the cycloalkyleneoxyalkyl group preferably includes 3 to 10 carbon atoms.

Examples of the C6 to C20 arylene group include a phenylene group, a naphthylene group, an anthracenylene group, and a biphenylene group.

Examples of the C7 to C20 aryleneoxyalkylene group include a phenyleneoxypropylene group, a naphthyleneoxypropylene group, an anthracenyleneoxypropylene group, and a biphenyleneoxypropylene group.

In this case, at least one of hydrogen atoms that constitute the C1 to C10 alkylene group, the C2 to C10 alkyleneoxyalkylene group, the C3 to C30 cycloalkylene group, the C4 to C30 cycloalkyleneoxyalkylene group, the C6 to C20 arylene group, and the C7 to C20 aryleneoxyalkylene group may be substituted with the above-mentioned C1 to C10 alkyl group.

Among them, R₂ is preferably the C2 to C10 alkyleneoxyalkylene group from the viewpoint of enhancing the leveling property, more preferably a methyleneoxymethylene group, a methyleneoxyethylene group, an ethyleneoxyethylene group, an ethyleneoxypropylene group, a propyleneoxypropylene group, a propyleneoxybutylene group, or a bwutyleneoxybutylene group from the viewpoint of enhancing solubility, and even more preferably an ethyleneoxyethylene group, an ethyleneoxypropylene group, or a propyleneoxypropylene group from the viewpoint of improving the electronic element characteristics.

R₃ is a vinyl group or an organic group including a vinyl group.

Examples of the organic group including a vinyl group include aliphatic hydrocarbon groups including a vinyl group such as an allyl group, a 2-butenyl group, a 3-butenyl group, a 3-pentenyl group, a 4-pentenyl group, a 5-hexenyl group, a butadienyl group, a 2,4-pentadienyl group, a 3,5-hexadienyl group, a 4,6-heptadienyl group, and a 5,7-octadienyl group; vinyloxyalkylene groups such as a vinyloxymethylene group, a vinyloxyethylene group, a vinyloxypropylene group, and a vinyloxybutylene group; a styryl group; aralkyl groups including a vinyl group such as a styryl methylene group, a styryl ethylene group, a styryl propylene group, and a styrylbutylene group; and styryloxyalkylene groups such as a styryloxymethylene group, a styryloxyethylene group, a styryloxypropylene group, and a styryloxybutylene group.

Among them, from the viewpoint of excellent polymerizability, a vinyl group, an aliphatic hydrocarbon group including a vinyl group, a styryl group, and an aralkyl group including a vinyl group are preferred, and from the viewpoint of easy designability of polymers of various molecular weights, a vinyl group, a butadienyl group, a pentadienyl group, a styryl group, and an aralkyl groups including a vinyl group are more preferred, and from the viewpoint that the resulting polymer improves the driving stability of the electronic element, a vinyl group, a butadienyl group, a 2,4-pentadienyl group, a styryl group, and a styrylmethylene group are even more preferred.

In the general formula, n is 1 to 1,000, preferably 3 to 500 from the viewpoint of allowing the coating film obtained from the electronic material composition or ink to exhibit excellent smoothness, and more preferably 5 to 200 from the viewpoint of improving driving stability of the electronic element.

Specific examples of the siloxane monomers of the present invention are shown below, but are not limited thereto.

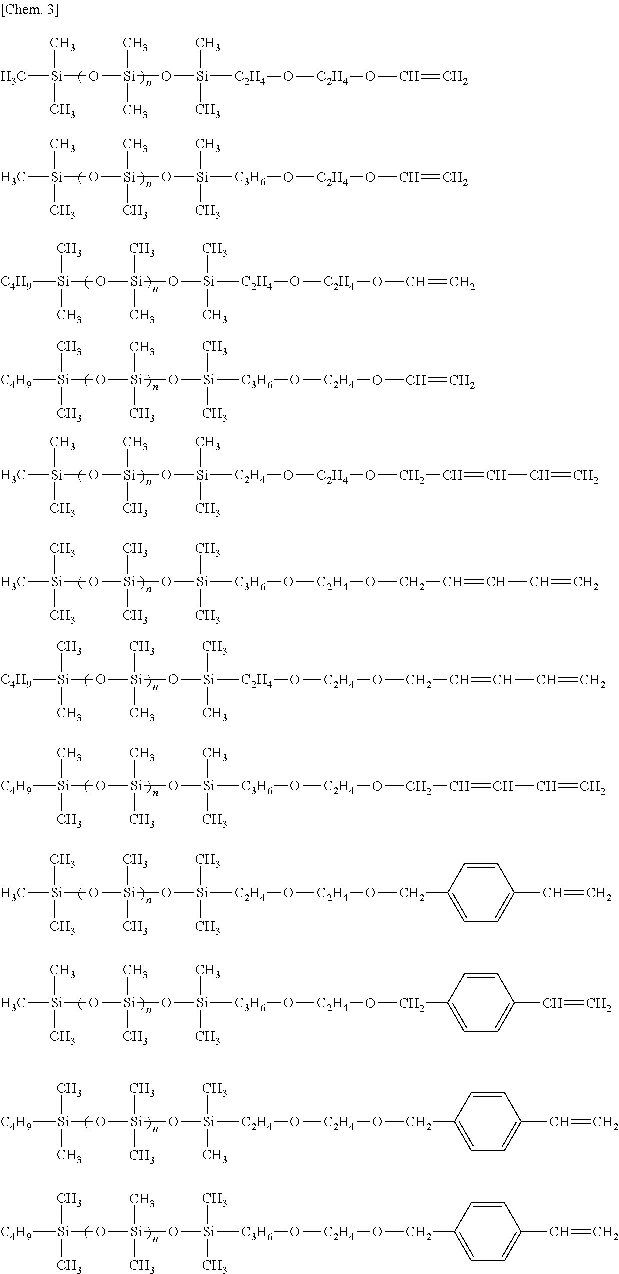

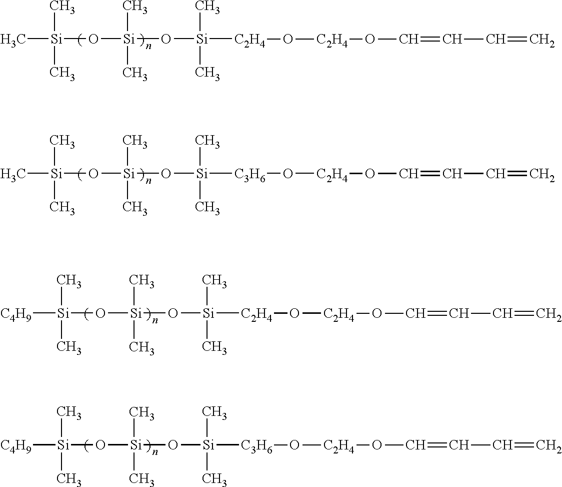

(In the above chemical formulae, n is an integer of 1 to 1,000.)

[Method of Preparing Siloxane Monomers]

There is no particular limitation on a method of preparing the siloxane monomers of the present invention; examples thereof include a method of reacting a siloxane compound including a hydroxyl group with a vinyl compound including a halogen group under the presence of a base.

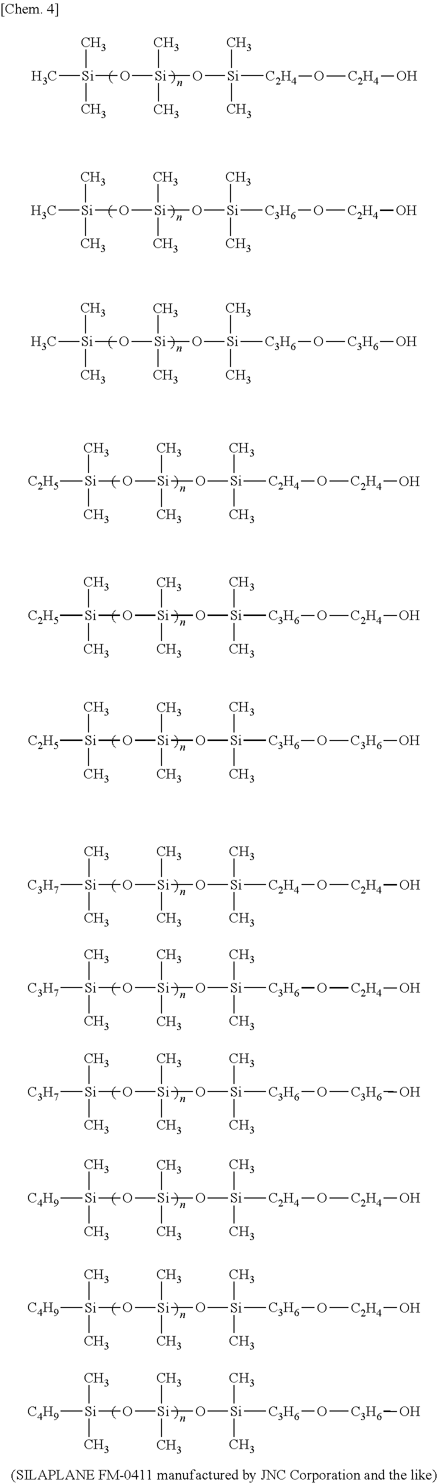

(In the above chemical formulae, n is an integer of 1 to 1,000.)

Examples of the vinyl compound including a halogen group include halogenated vinyl compounds such as vinyl bromide, and vinyl chloride; halogenated vinyl alkylene compounds such as allyl bromide, allyl chloride, vinyl ethylene bromide, vinyl ethylene chloride, vinyl propylene bromide, and vinyl propylene chloride; halogenated butadiene compounds such as 4-bromo-1,3-butadiene, and 4-chloro-1,3-butadiene; halogenated alkyldiene compounds such as 5-bromo-1,3-pentadiene, 5-chloro-1,3-pentadiene, 6-bromo-1,3-hexadiene, 6-chloro-1,3-hexadiene, 7-bromo-1,3-heptadiene, and 7-chloro-1,3-heptadiene; halogenated styryl compounds such as 4-bromostyrene, and 4-chlorostyrene; halogenated alkylene styryl compounds such as 4-bromomethylstyrene, 4-chloromethylstyrene, 4-bromoethylstyrene, and 4-chloroethyl styrene, but are not limited thereto.

There is no particular limitation on the base; examples thereof include sodium hydroxide, potassium hydroxide, cesium hydroxide, sodium hydride, sodium tert-butoxide, potassium tert-butoxide, sodium methoxide, and potassium methoxide.

In the above reaction, there is no particular limitation on the amount of materials to be charged, but from the viewpoint of yield, it is preferable to add 1 to 5 equivalents of the vinyl compound including a halogen group to the siloxane compound including a hydroxyl group. The added amount of the base to be charged is preferably 1 to 5 equivalents to the siloxane including a hydroxyl group. The reaction temperature is preferably 10 to 80° C., and the reaction atmosphere is preferably an inert gas atmosphere. A catalyst such as potassium iodide may be optionally added.

[Polymer Obtained by Polymerizing Siloxane Monomer]

The polymer obtained by polymerizing the siloxane monomer of the present invention may be any of a polymer obtained by homopolymerizing one of the siloxane monomers represented by general formula (1) and a polymer obtained by copolymerizing one of the siloxane monomers represented by general formula (1) and a monomer other than the monomers represented by general formula (1).

There is no particular limitation on the monomer other than the monomers represented by the general formula (1), for example, and commonly known (meth)acrylate monomers, styryl monomers, vinyl ether monomers, and allyl monomers and the like may be used.

There is no particular limitation on the (meth)acrylate monomers; examples thereof include alkyl(meth)acrylate esters such as methyl (meth)acrylate, ethyl (meth)acrylate, propyl (meth)acrylate, n-butyl (meth)acrylate, t-butyl (meth)acrylate, hexyl (meth)acrylate, heptyl (meth)acrylate, octyl (meth)acrylate, nonyl (meth)acrylate, decyl (meth)acrylate, dodecyl (meth)acrylate, tetradecyl (meth)acrylate, hexadecyl (meth)acrylate, octadecyl (meth)acrylate, and docosyl (meth)acrylate; cycloalkyl (meth)acrylate esters such as cyclohexyl(meth)acrylate, isobornyl (meth)acrylate, dicyclopentanyl (meth)acrylate, and dicyclopentanyloxyethyl (meth)acrylate; aryl (meth)acrylate esters such as benzoyloxyethyl (meth)acrylate, benzyl (meth)acrylate, phenylethyl (meth)acrylate, phenoxyethyl (meth)acrylate, phenoxydiethyl glycol (meth)acrylate, and 2-hydroxy-3-phenoxypropyl (meth)acrylate.

There is no particular limitation on the styryl monomers, and examples thereof include styrene and styrene derivatives such as alkyl-substitutedstyrene, e.g., α-methylstyrene, α-ethylstyrene, α-butylstyrene, and 4-methylstyrene, and chlorostyrene.

There is no particular limitation on the vinyl ether monomer; examples thereof include alkyl vinyl ethers such as methyl vinyl ether, ethyl vinyl ether, propyl vinyl ether, isopropyl vinyl ether, n-butyl vinyl ether, sec-butyl vinyl ether, tert-butyl vinyl ether, isobutyl vinyl ether, n-amyl vinyl ether, and isoamyl vinyl ether; cycloalkyl vinyl ethers such as cyclopentyl vinyl ether, cyclohexyl vinyl ether, cycloheptyl vinyl ether, cyclooctyl vinyl ether, 2-bicyclo[2.2.1]heptyl vinyl ether, 2-bicyclo[2.2.2]octyl vinyl ether, 8-tricyclo[5.2.1.0(2,6)]decanyl vinyl ether, 1-adamantyl vinyl ether, and 2-adamantyl vinyl ether; aryl vinyl ethers such as phenyl vinyl ether, 4-methylphenyl vinyl ether, 4-trifluoromethylphenyl vinyl ether, and 4-fluorophenyl vinyl ether; and aryl vinyl ethers such as benzyl vinyl ether, and 4-fluorobenzyl vinyl ether.

There is no particular limitation on the allyl monomers; examples thereof include alkyl allyl ethers such as methyl allyl ether, ethyl allyl ether, propyl allyl ether, and butyl allyl ether; and aryl allyl ethers such as phenyl allyl ether; allyl acetate, allyl alcohol, and allylamine.

In particular, these (meth)acrylate monomers, the styryl monomers, the vinyl ether monomers, and the allylic monomers preferably include a hydrophobic group. In the present specification, the term “hydrophobic group” refers to a group, where the solubility in water (25° C., 25% RH) of a molecule formed by bonding a hydrophobic group to a hydrogen atom is 100 mg/L or less.

There is no particular limitation on the hydrophobic group; examples thereof include a C1 to C18 alkyl group, a C3 to C20 cycloalkyl group, and a C6 to C 30 aryl group.

There is no particular limitation on the C1 to C18 alkyl group; examples thereof include a methyl group, an ethyl group, a propyl group, an isopropyl group, a butyl group, an iso-butyl group, a sec-butyl group, a tert-butyl group, a pentyl group, a hexyl group, a decyl group, an undecyl group, a dodecyl group, an octadecyl group, and a 2-ethylhexyl group.

There is no particular limitation on the C3 to C20 cycloalkyl group; examples thereof include a cyclopropyl group, a cyclobutyl group, a cyclopentyl group, a cyclohexyl group, a cycloheptyl group, tricyclo[5,2,1,0(2,6)] decyl group, and an adamantyl group.

Examples of the C6 to C30 aryl group include phenyl, naphthyl, anthracenyl, and biphenyl.

Examples of monomers including such a hydrophobic group include alkyl (meth)acrylate esters, cycloalkyl (meth)acrylate esters, aryl (meth)acrylate esters, styrene, alkyl-substituted styrenes, alkyl vinyl ethers, cycloalkyl vinyl ethers, aryl vinyl ethers, alkyl allyl ethers, and aryl allyl ethers.

Among the monomers including a hydrophobic group, from the viewpoint of satisfactory copolymerizability to the monomers represented by the general formula (1) and obtaining polymers with various molecular weights, preferable examples include the alkyl (meth)acrylate esters, cycloalkyl (meth)acrylate esters, aryl (meth)acrylate esters, styrene, alkyl-substituted styrenes, alkyl vinyl ethers, cycloalkyl vinyl ethers, and aryl vinyl ethers. From the viewpoint that the resulting polymer more favorably exhibits the leveling property improving effect, it is preferable to use an aromatic compound-containing monomer including an aryl group such as aryl (meth)acrylate esters, styrene, alkyl-substituted styrenes, and aryl vinyl ethers, and from the viewpoint of driving stability of the electronic element, styrene, alkyl-substituted styrenes, and aryl vinyl ether are more preferable, and when styrene, alkyl-substituted styrenes, phenyl vinyl ether, or benzyl vinyl ether is employed, the effect of the present invention is particularly remarkable.

The above-mentioned monomers may be used singly, and two or more thereof may be used in combination.

The weight-average molecular weight (Mw) of the polymer of the present invention is preferably 500 to 100,000, and more preferably 3,000 to 40,000 from the viewpoint of smoothness. Note that, in the present specification, the value of “weight-average molecular weight (Mw)” refers to a value obtained according to the measurement method shown in Examples.

The number-average molecular weight (Mn) of the polymer of the present invention is preferably 500 to 100,000, and more preferably 3,000 to 40,000 from the viewpoint of smoothness. Furthermore, in the present specification, the value of “number-average molecular weight (Mn) refers to a value obtained according to the measurement method shown in Examples.

[Method of Preparing Polymer]

The polymer of the present invention may be obtained through any commonly known method for polymerization (copolymerization) using the above-mentioned monomers and polymerization initiator, and the polymer may be any of a random copolymer, a block copolymer, and a graft copolymer.

Examples of the polymerization method include radical polymerization, anionic polymerization, and cationic polymerization.

The radical polymerization is not carried out under particularly limited reaction condition; the radical polymerization may be carried out in a solvent using a monomer and radical polymerization initiator, for example.

Any commonly known radical polymerization initiators may be used; examples thereof include azo compounds such as 2,2′-azobisisobutyronitrile, 2,2′-azobis-(2,4-dimethylvaleronitrile), and 2,2′-azobis-(4-methoxy-2,4-dimethylvaleronitrile); and organic peroxides such as benzoyl peroxide, lauroyl peroxide, t-butyl peroxypivalate, t-butyl peroxyethyl hexanoate, 1,1′-bis-(t-butylperoxy)cyclohexane, t-amylperoxy-2-ethylhexanoate, and t-hexylperoxy-2-ethylhexanoate and hydrogen peroxides. These may be used singly, and two or more thereof may be used in combination.

There is no particular limitation on the use amount of the radical polymerization initiator; the use amount is typically 0.001 parts to 1 part by mass with respect to 100 parts by mass of the monomer. In obtaining the polymer of the present invention within the range of the above-mentioned preferable weight-average molecular weight, the use amount of the radical polymerization initiator is preferably 0.005 to 0.5 parts by mass, and more preferably 0.01 to 0.3 parts by mass, with respect to 100 parts by mass of the monomer.

Representative examples of the solvent that may be used for the radical polymerization include ketone solvents such as acetone, methyl ethyl ketone, methyl-n-propyl ketone, methyl isopropyl ketone, methyl-n-butyl ketone, methyl isobutyl ketone, methyl-n-amyl ketone, methyl-n-hexyl ketone, diethyl ketone, ethyl-n-butyl ketone, di-n-propyl ketone, diisobutyl ketone, cyclohexanone, and holon;

ether solvents such as ethyl ether, isopropyl ether, n-butyl ether, diisoamyl ether, ethylene glycol dimethyl ether, ethylene glycol diethyl ether, diethylene glycol dimethyl ether, diethylene glycol, dioxane, and tetrahydrofuran;

ester solvents such as ethyl formate, propyl formate, n-butyl formate, ethyl acetate, n-propyl acetate, isopropyl acetate, n-butyl acetate, n-amyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, and ethyl-3-ethoxypropionate;

alcoholic solvents such as methanol, ethanol, isopropyl alcohol, n-butyl alcohol, isobutyl alcohol, diacetone alcohol, 3-methoxy-1-propanol, 3-methoxy-1-butanol, and 3-methyl-3-methoxybutanol; and

hydrocarbon solvents such as toluene, xylene, Solvesso 100, Solvesso 150, Swazole 1800, Swazole 310, Isopar E, Isopar G, Exxon Naphtha no. 5, and Exxon Naphtha no. 6.

These solvents may be used singly, and two or more thereof may be used in combination.

There is no particular limitation on the use amount of the solvent in the radical polymerization reaction; and the use amount is preferably 0 parts to 3,000 parts by mass from the viewpoint of stirring property more preferably 10 parts to 1,000 parts by mass from the viewpoint of reactivity, and even more preferably 10 parts to 500 parts by mass from the viewpoint of molecular weight controllability, with respect to 100 parts by mass of the charged amount of the monomer.

The reaction condition for the anionic polymerization is not limited particularly, and the anionic polymerization may be carried out in a solvent using a monomer and an anionic polymerization initiator, for example.

Any commonly known anionic polymerization initiator may be used; examples thereof include organic alkali metals such as methyl lithium, n-butyl lithium, sec-butyl lithium, t-butyl lithium, isopropyl lithium, n-propyl lithium, isopropyl lithium, phenyl lithium, benzyl lithium, hexyl lithium, butyl sodium, and butyl potassium; organic alkaline earth metals such as methyl magnesium chloride, methyl magnesium bromide, methyl magnesium iodide, ethyl magnesium bromide, propyl magnesium bromide, phenyl magnesium chloride, phenyl magnesium bromide, and dibutyl magnesium; alkali metals such as lithium, sodium, and potassium; organic zinc such as diethyl zinc, dibutyl zinc, and ethyl butyl zinc; and organic aluminum such as trimethyl aluminum, triethyl aluminum, methyl bisphenoxy aluminum, isopropyl bisphenoxy aluminum, bis(2,6-di-t-butylphenoxy)methyl aluminum, and bis(2,6-di-t-butyl-4-methylphenoxy)methyl aluminum. These initiators may be used singly or two or more thereof may be used in combination.

There is no particular limitation on the use amount of the anionic polymerization initiator to be used; the use amount is preferably 0.001 parts to 1 part by mass, more preferably 0.005 parts to 0.5 parts by mass, and even more preferably 0.01 parts to 0.3 parts by mass, with respect to 100 parts by mass of the monomer.

The examples of the solvent that may be used for the anionic polymerization include the above-mentioned solvents.

There is no particular limitation on the use amount of the solvent used in the anionic polymerization reaction; the use amount is preferably 0 parts to 3,000 parts by mass from the viewpoint of stirring property, more preferably 10 parts to 1,000 parts by mass from the viewpoint of reactivity, and even more preferably 10 parts to 500 parts by mass from the viewpoint of molecular weight controllability, with respect to 100 parts by mass of the charged amount of the monomer.

The reaction condition for the cationic polymerization is not particularly limited, and the cationic polymerization may be carried out, for example, in a solvent using a monomer and a cationic polymerization initiator.

Any commonly known cationic polymerization initiator may be used; examples thereof include protonic acids such as hydrochloric acid, sulfuric acid, perchloric acid, trifluoroacetic acid, methanesulfonic acid, trifluoromethanesulfonic acid, chlorosulfonic acid, and fluorosulfonic acid; and lewis acids such as boron trifluoride, aluminum chloride, titanium tetrachloride, stannic chloride, and ferric chloride. These initiators may be used singly, or two or more thereof may be used in combination.

There is no particular limitation on the use amount of the cationic polymerization initiator; the use amount is typically 0.001 parts to 1 part by mass, with respect to 100 parts by mass of the monomer. In obtaining the polymer of the present invention having a weight average molecular weight falling within the preferable range mentioned above, the use amount of the cationic polymerization initiator is preferably 0.005 parts to 0.5 parts by mass, and more preferably 0.01 parts to 0.3 parts by mass, with respect to 100 parts by mass of the monomer.

The examples of the solvent that may be used for the cationic polymerization include the solvents that may be used for the above-mentioned radical polymerization.

There is no particular limitation on the use amount of the solvent in the cationic polymerization reaction; the use amount is preferably 0 parts to 3,000 parts by mass from the viewpoint of stirring property, more preferably 10 parts to 51,000 parts by mass from the viewpoint of reactivity, and even more preferably 10 parts to 500 parts by mass from the viewpoint of molecular weight controllability, with respect to 100 parts by mass of the charged amount of the monomer.

The radical polymerization, anionic polymerization, and cationic polymerization may be carried out in a form of living polymerization; methods described in “Quarterly Chemistry Review No. 18, 1993, Precise polymerization edited by Chemical Society of Japan (Academic Press Center)” may be used, for example.

[Composition]

The composition containing the polymer of the present invention has a function of improving the leveling property after film formation, and thus may be used for curing compositions to be cured by heat or light, ink compositions, coating compositions, and electronic material compositions, but the application thereof is not limited thereto. Among them, the polymer of the present invention is useful for the electronic material compositions since the electric characteristics of the electronic element is not deteriorated.

[Electronic Material Composition]

The electronic material composition containing the polymer of the present invention includes an organic semiconductor material, the polymer (leveling agent) of the present invention, and a solvent. The electronic material composition may further include a surfactant or the like other than the above materials, as necessary.

The content of the organic semiconductor material is preferably 0.01% to 10% by mass, and more preferably 0.01% to 5% by mass from the viewpoint of electrical characteristics, with respect to the total amount of the electronic material composition.

The content of the polymer of the present invention is preferably 0.001% to 5.0% by mass, and more preferably 0.001% to 1.0% by mass from the viewpoint of leveling property, with respect to the total amount of the electronic material composition.

The content of the solvent is preferably 90% to 99% by mass, and more preferably 95% to 99% by mass from the viewpoint of film formability, with respect to the total amount of the electronic material composition.

(Organic Semiconductor Material)

Examples of the organic semiconductor material include organic TFT materials, organic solar cell materials, and organic EL materials, but are not limited thereto.

There is no particular limitation on the organic TFT material so long as the material can be used for a layer constituting the organic TFT element; examples thereof include acenes which may have a substituent such as naphthalene, anthracene, tetracene, pentacene, hexacene, and heptacene, e.g., compounds having a styryl structure represented by C₆H₅—CH═CH—C₆H₅ such as 1,4-bistyrylbenzene, 1,4-bis(2-methylstyryl)benzene, 1,4-bis (3-methylstyryl)benzene (4MSB), 1,4-bis(4-methylstyryl)benzene, and polyphenylene vinylene, oligomers and polymers of such compounds, thiophene oligomers which may have a substituent such as derivatives of α-4T, α-5T, α-6T, α-7T, and α-8T, thiophene polymers such as polyhexylthiophene and poly(9,9-dioctylfluorenyl-2,7-diyl-co-bithiophene), condensed oligothiophenes, in particular, compounds having a thienobenzene skeleton or a dithienobenzene skeleton, such as bisbenzothiophene derivatives, α,α′-bis(dithieno[3,2-b: 2′,3′-d]thiophene), co-oligomer of dithienothiophene-thiophene, and pentathienoacene, [1]benzothieno[3,2-b][1]benzothiophene derivatives, selenophene oligomers, porphyrins such as metal-free phthalocyanine, copper phthalocyanine, lead phthalocyanine, titanyl phthalocyanine, platinum porphyrin, porphyrin, and benzoporphyrin, tetrathiafulvalene (TTF) and derivatives thereof, rubrene and derivatives thereof, tetracyanoquinodimethane (TCNQ), quinoid oligomer of 11,11,12,12-tetracyano naphtho-2,6-quinodimethane (TCNNQ), fullerenes such as C60, C70, and PCBM, and tetracarboxylic acids such as N,N′-diphenyl-3,4,9,10-perylene tetracarboxylate diimide, N,N′-dioctyl-3,4,9,10-perylenetetracarboxylate diimide(C8-PTCDI), NTCDA, and 1,4,5,8-naphthalenetetracarboxylate diimide (NTCDI).

There is no particular limitation on the organic solar cell material so long as the material can be used for a layer constituting an organic solar cell element; examples thereof include fullerenes such as C60 and C70, fullerene derivatives, carbon nanotubes, perylene derivatives, polycyclic quinones, and quinacridone, and examples of polymers that can be further exemplified as the organic solar cell material include CN-poly(phenylene-vinylene), MEH-CN-PPV, polymers containing —CN group or —CF₃ group, —CF₃-substituted polymers thereof, and poly(fluorene) derivatives.

There is no particular limitation on the organic EL material so long as the material can be used for a layer constituting an organic EL element. In one embodiment, examples of the organic EL material that the electronic material composition may contain include light emitting materials used for a light emitting layer, hole injection materials used for a hole injection layer, hole transport materials used for a hole transport layer, and electron transport materials used for an electron transport layer.

(Light Emitting Material)

A light emitting material includes a host material and a dopant material.

While the composition ratio of the host material to the dopant material is not limited, the dopant is preferably 1 part to 50 parts by mass, and more preferably 5 parts to 20 parts by mass from the viewpoint of luminous efficiency, with respect to 100 parts by mass of the host.

The host material is classified into a high molecular weight host material and a low molecular weight host material. In the present specification, “low molecular weight” means a weight-average molecular weight (Mw) of 5,000 or less. On the other hand, in the present specification, “high molecular weight” means a weight average molecular weight (Mw) of more than 5,000. In the present specification, “weight-average molecular weight (Mw)” is a value measured through gel permeation chromatography (GPC) using polystyrene as the standard substance.

The high molecular weight host material is not particularly limited; examples thereof include poly(9-vinylcarbazole)(PVK), polyfluorene (PF), polyphenylene vinylene(PPV), and copolymers containing these monomer units.

The weight-average molecular weight (Mw) of the high molecular weight host material is preferably more than 5,000 and 5,000,000 or less, and more preferably more than 5,000 and 1,000,000 or less from the viewpoint of film formability.

The low molecular weight host material is not particularly limited; examples thereof include carbazole derivatives such as 4,4′-bis(9H-carbazol-9-yl) biphenyl (CBP), 4,4′-bis(9-carbazolyl)-2,2′-dimethylbiphenyl (CDBP), N,N′-dicarbazolyl-1,4-dimethylbenzene (DCB), 1,3-dicarbazolylbenzene (mCP), 3,5-bis(9-carbazolyl) tetraphenylsilane (SimCP), 9,9′-(p-tert-butylphenyl)-1,3-biscarbazole, silane derivatives such as 4,4′-di(di(triphenylsilyl)-biphenyl (BSB), 9-(4-tert-butylphenyl)-3,6-bis(triphenylsilyl)-9H-carbazole (CzSi), and 1,3-bis(triphenylsilyl) benzene (UGH 3), metal complexes such as bis(2-methyl-8-quinolinolate)-4-(phenylphenolato)aluminum (BAlq), phosphine oxide derivatives such as 2,7-bis(diphenylphosphine oxide)-9,9-dimethylfluorescein (906), amine derivatives such as 1,3,5-tris[4-(diphenylamino)phenyl]benzene (TDAPB), and heterocyclic compounds such as oxadiazole derivatives, imidazole derivatives, triazine derivatives, pyridine derivatives, and pyrimidine derivatives.

The weight-average molecular weight (Mw) of the low molecular weight host material is preferably 100 to 5,000, and more preferably 300 to 5,000 from the viewpoint of film formability.

Among the host materials, the host material to be used is preferably the low molecular weight host material, more preferably carbazole derivatives such as 4,4′-bis(9H-carbazol-9-yl)biphenyl (CBP) and 9,9′-(p-tert-butylphenyl)-1,3-biscarbazole, bis(2-methyl-8-quinolinolate)-4-(phenylphenolato)aluminum (BAlq), heterocyclic compounds such as oxadiazole derivatives, imidazole derivatives, triazine derivatives, pyridine derivatives, and pyrimidine derivatives, and even more preferably 4,4′-bis(9H-carbazol-9-yl)biphenyl (CBP), 9,9′-(p-tert-butylphenyl)-1,3-biscarbazole, and heterocyclic compounds such as imidazole derivatives, triazine derivatives, pyridine derivatives, and pyrimidine derivatives.

The host material may be used singly or two or more thereof may be used in combination.

The dopant material is usually classified into a high molecular weight dopant material and a low molecular weight dopant material.

There is no particular limitation on the high molecular weight dopant material; examples thereof include polyphenylene vinylene (PPV), cyanopolyphenylene vinylene (CN-PPV), poly(fluorenyleneethynylene) (PFE), polyfluorene (PFO), polythiophene polymer, polypyridine, and copolymers containing these monomer units.

The weight-average molecular weight (Mw) of the high molecular weight dopant material is preferably more than 5,000 and 5,000,000 or less, and more preferably more than 5,000 and 1,000,000 or less from the viewpoint of luminous efficiency.

The low molecular weight dopant material is not particularly limited; examples thereof include fluorescent materials, and phosphorescent materials.

Examples of the fluorescent material include naphthalene, perylene, pyrene, chrysen, anthracene, coumarin, p-bis(2-phenylethenyl)benzene, quinacridone, coumarin, aluminum complexes such as Al(C₉H₆NO)₃, rubrene, perimidone, dicyanomethylene-2-methyl-6-(p-dimethylaminostyryl)-4H-pyr an (DCM), benzopyran, rhodamine, benzothioxanthene, azabenzothioxanthene, and derivatives thereof.

Examples of the phosphorescent material include complexes in which a central metal belonging to Group 7 to Group 11 in the periodic table, and aromatic ligands coordinated to the central metal are included.

Examples of the central metal belong to Groups 7 to 11 in the periodic table include ruthenium, rhodium, palladium, osmium, iridium, gold, platinum, silver, and copper. Among those, the central metal is preferably iridium from the viewpoint of luminous efficiency.

Examples of the ligands include phenyl pyridine, p-tolylpyridine, thienylpyridine, difluorophenyl pyridine, phenylisoquinoline, fluorenopyridine, fluorenoquinoline, acetylacetone, and derivatives thereof. Among these, the ligand is preferably phenyl pyridine, p-tolylpyridine, and derivatives thereof, and more preferably p-tolylpyridine and derivatives thereof from the viewpoint of film formability.

Specific examples of the phosphorescent material include tris(2-phenylpyridine) iridium (Ir(ppy)₃), tris(2-phenylpyridine)ruthenium, tris(2-phenylpyridine)palladium, bis(2-phenylpyridine)platinum, tris(2-phenylpyridine)osmium, tris(2-phenylpyridine)rhenium, tris[2-(p-tolyl)pyridine]iridium (Ir(mppy)₃), tris[2-(p-tolyl)pyridine]ruthenium, tris[2-(p-tolyl)pyridine]palladium, tris[2-(p-tolyl)pyridine]platinum, tris[2-(p-tolyl)pyridine]osmium, tris[2-(p-tolyl)pyridine]rhenium, octaethyl platinum porphyrin, octaphenyl platinum porphyrin, octaethyl palladium porphyrin, and octaphenyl palladium porphyrin.

Among those, the dopant material is preferably the low molecular weight dopant material, and preferably the phosphorescent material from the viewpoint of luminous efficiency.

The weight-average molecular weight (Mw) of the low molecular weight dopant material is preferably 100 to 5,000, and is more preferably 100 to 3,000.

The dopant materials may be used singly and two or more thereof may be used in combination.

Among those, the light emitting material is preferably the low molecular weight light emitting materials and more preferably the low molecular host material and the low molecular dopant material from the viewpoint of obtaining a higher luminous efficiency.

(Hole Injection Material)

The hole injection material is not particularly limited; examples thereof include phthalocyanine compounds such as copper phthalocyanine; triphenylamine derivatives such as 4,4′,4″-tris[phenyl(m-tolyl)amino]triphenylamine; cyano compounds such as 1,4,5,8,9,12-hexaazatriphenylene hexacarbonitrile and 2,3,5,6-tetrafluoro-7,7,8,8-tetracyano-quinodimethane; oxides such as vanadium oxides and molybdenum oxides; amorphous carbon; and polymers such as polyaniline (emeraldine), poly(3,4-ethylenedioxythiophene)-poly (styrenesulfonate) (PEDOT-PSS), and polypyrrole. Among these, the hole injection material is preferably a polymer, from the viewpoint of film formability.

The hole injection materials may be used singly, or two or more thereof may be used in combination.

(Hole Transport Material)

The hole transport material is not particularly limited; example thereof include low molecular weight triphenylamine derivatives such as TPD (N,N′-diphenyl-N,N′-di(3-methylphenyl)-1,1′-biphenyl-4,4′diamine), α-NPD (4,4′-bis[N-(1-naphthyl)-N-phenylamino]biphenyl), m-MTDATA (4,4′,4″-tris(3-methylphenylphenylamino)triphenylamine); polyvinylcarbazole; and a polymer compound represented by the following chemical formula HT-2 obtained by polymerizing a triphenylamine derivative in which a substituent is introduced. Among these, the hole transport material is preferably triphenylamine derivative, and a polymer compound such as HT-2 represented by chemical formula 5 obtained by polymerizing a triphenylamine derivative in which a substituent is introduced from the viewpoint of hole transportability.

The hole transport materials may be used singly and two or more thereof may be used in combination.

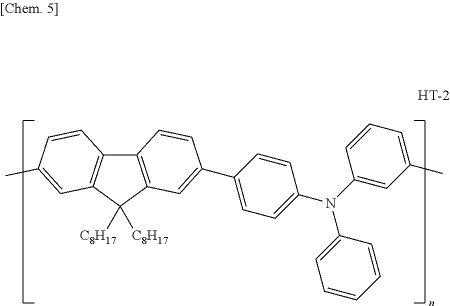

(Electron Transport Material)

There is no particular limitation on the electron transport material; examples thereof include metal complexes including a quinoline skeleton or a benzoquinoline skeleton such as tris(8-quinolilato)aluminum (Alq), tris(4-methyl-8-quinolinolato)aluminum (Almq3), bis(10-hydroxybenzo[h]quinolinato)beryllium (BeBq2), bis(2-methyl-8-quinolinolato)(p-phenylphenolato)aluminum (BAlq), bis(8-quinolinolato)zinc (Znq); metal complexes including a benzoxazoline skeleton such as bis[2-(2′-hydroxyphenyl)benzoxazolate]zinc (Zn(BOX)2); metal complexes including a benzothiazoline skeleton such as bis[2-(2′-hydroxyphenyl)benzothiazolato]zinc (Zn(BTZ)2); polyazole derivatives such as 2-(4-biphenylyl)-5-(4-tert-butylphenyl)-1,3,4-oxadiazole(P BD), 3-(4-biphenylyl)-4-phenyl-5-(4-tert-butylphenyl)-1,2,4-tri azole (TAZ), 1,3-bis[5-(p-tert-butylphenyl)-1,3,4-oxadiazol-2-yl]benzen e(OXD-7), 9-[4-(5-phenyl-1,3,4-oxadiazol-2-yl)phenyl]carbazole (CO11), 2,2′,2″-(1,3,5-benzenetriyl)tris(1-phenyl-1H-benzimidazole (TPBI), and 2-[3-(dibenzothiophen-4-yl)phenyl]-1-phenyl-1H-benzimidazole (mDBTBIm-II); benzimidazole derivatives such as ET-1 represented by chemical formula 6; quinoline derivatives; perylene derivatives; pyridine derivatives; pyrimidine derivatives; triazine derivatives; quinoxaline derivatives; diphenylquinone derivatives; and nitro-substituted fluorene derivatives. Among these, the electron transport material is preferably the benzimidazole derivatives, the pyridine derivatives, the pyrimidine derivatives, and the triazine derivatives, from the viewpoint of electron transportability.

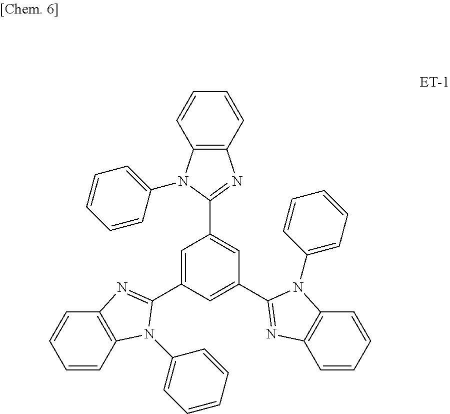 [SMILES: c1ccc(-n2c(-c3cc(-c4nc5ccccc5n4-c4ccccc4)cc(-c4nc5ccccc5n4-c4ccccc4)c3)nc3ccccc32)cc1]

The electron transport materials may be used singly, or two or more thereof may be used in combination.

(Solvent)

Any solvent considered as appropriate may be used without particular limitation. Specific examples thereof include aromatic solvents, alkane solvents, ether solvents, alcohol solvents, ester solvents, amide solvents, and other solvents.

Examples of the aromatic solvent include monocyclic aromatic solvents such as toluene, xylene, ethylbenzene, cumene, pentylbenzene, hexylbenzene, cyclohexylbenzene, dodecylbenzene, mesitylene, diphenylmethane, dimethoxybenzene, phenetol, methoxytoluene, anisole, methylanisole, and dimethylanisole; condensed cyclic aromatic solvents such as cyclohexylbenzene, tetralin, naphthalene, and methylnaphthalene; ether aromatic solvents such as methylphenylether, ethylphenylether, propylphenylether, and butylphenylether; and ester aromatic solvents such as phenyl acetate, phenyl propionate, ethyl benzoate, propyl benzoate, and butyl benzoate.

Examples of the alkane solvent include pentane, hexane, octane, and cyclohexane.

Examples of the ether solvent include dioxane, ethylene glycol dimethyl ether, ethylene glycol diethyl ether, propylene glycol-1-monomethyl ether acetate, and tetrahydrofuran.

Examples of the alcohol solvent include methanol, ethanol, and isopropyl alcohol.

Examples of the ester solvent include ethyl acetate, butyl acetate, ethyl lactate, and butyl lactate.

Examples of the amide solvent include N,N-dimethylformamide, and N,N-dimethylacetamide.

Examples of the other solvent include water, dimethyl sulfoxide, acetone, chloroform, and methylene chloride.

Among these, the solvent is preferably an aromatic solvent from the viewpoint of solubility of the organic semiconductor material, more preferably a solvent containing at least one selected from the group consisting of the condensed cyclic aromatic solvent, the ether aromatic solvent, and ester aromatic solvent from the viewpoint of leveling property, and even more preferably a solvent containing the condensed cyclic aromatic solvent and/or the ether aromatic solvent from the viewpoint of film formability.

The above described solvent may be used singly, or two or more thereof may be used in combination.

In a case where a coating film is formed by applying the electronic material composition according to the embodiment, the presence of the siloxane structure in the polymer of the present invention, which serves as a leveling agent, causes the polymer to be aligned on the surface of the coating film and lowers the surface tension. In the case of drying the coating film obtained in such a state, undulation due to drying can be prevented, and a layer having a high degree of flatness, further, an organic functional layer exhibiting excellent performance can be provided.

In one embodiment, in a case where the electronic material composition in forming the light emitting layer of the organic EL element is used, the material composition even plays a role of improving the driving stability of the organic EL element. Such a function is believed to be exhibited because the siloxane structure in the polymer of the present invention does not include carbonyl group, which serves as a carrier trap site.

More specifically, in one embodiment, the light emitting material includes the host material and the dopant material. In the light emitting layer, the holes and/or electrons are transported through the host material, and the energy generated by recombination of holes and electrons transported to the dopant material causes the light emitting layer to emit light. In other words, once the holes and the electrons in the light emitting layer are efficiently transported, efficient light emission is enabled, thereby improving the driving stability.

The leveling agents in the related art contained in the electronic material composition are aligned on the surface of the coating film obtained by applying the ink composition and lowers the surface tension thereby enabling production of smooth coating film, but the siloxane structure of the leveling agents includes functional groups serving as the carrier trap sites due to the polarized charges therein, and the presence of these trap sites may disrupt the charge transport and may instabilize driving of the element. That is, the use of the leveling agents in the related art may achieve undulation prevention effect to some extent, but may also sacrifice driving stability instead.

In contrast, in a case where the siloxane structure of the leveling agent does not include a functional group in which charges are polarized, it is possible to prevent disruption of the charge transport. As a result, the charges are allowed to be efficiently transported in the light emitting layer, which consequently leads to improved driving stability.

[Electronic Element]

The electronic element of the present invention will be described. The electronic element of the present invention is an electronic element which contains a composition or an electronic material composition containing the polymer of the present invention, in any form. Specific examples of the electronic element include photoelectric conversion elements such as a solar cell or a light receiving element, transistors such as a field effect transistor, static induction transistor and bipolar transistor, organic electroluminescent elements (hereinafter abbreviated as “organic EL element”), a temperature sensor, a gas sensor, a humidity sensor, and a radiation sensor, but are not limited thereto.

As an example, the organic EL element will be described below.

<Organic EL Element>

According to one aspect of the present invention, there is provided an organic EL element including an anode, a light emitting layer, and a cathode. In this case, the light emitting layer is formed of an electronic material composition.

The organic EL element may include one or more other layers such as a hole injection layer, a hole transport layer, an electron transport layer, and an electron injection layer. Also, commonly known elements such as a sealing member may further be included.

According to another embodiment, there is provided an organic EL element including an anode, a light emitting layer, and a cathode, and at least one layer selected from the group consisting of a hole injection layer, a hole transport layer, an electron transport layer, and an electron injection layer. In this case, at least one layer selected from the group consisting of the light emitting layer, the hole injection layer, the hole transport layer, and the electron transport layer included in the organic EL element includes the polymer (leveling agent) of the present invention.

That is, the organic EL element includes the anode, the light emitting layer, and the cathode as essential constitutional units, and may further include at least one layer selected from the group consisting of the hole injection layer, the hole transport layer, the electron transport layer, and the electron injection layer as an optional structural unit. In this case, the leveling agent may be included only in the light emitting layer, or may be included only in at least one layer selected from the group consisting of the hole injection layer, the hole transport layer, and the electron transport layer (for example, only in the hole transport layer, or in the hole transport layer and the electron transport layer), or may be included in at least one layer of the light emitting layer, the hole injection layer, the hole transport layer, and the electron transport layer. In this case, it is preferable that the light emitting layer and/or the hole transport layer include the leveling agent, and it is more preferable that the light emitting layer includes the leveling agent.

Each of the constituents of the organic EL element will be described in detail below.

[Anode]

There is no particular limitation on the anode; examples of materials that may be used for the anode include metals such as gold (Au), and copper iodide (CuI), indium tin oxide (ITO), tin oxide (SnO₂), and zinc oxide (ZnO). These materials may be used singly, or two or more thereof may be used in combination.

Although there is no particular limitation on the film thickness of the anode, the thickness is preferably 10 nm to 1,000 nm, and more preferably 10 nm to 200 nm.

The anode may be formed through methods such as vapor deposition or sputtering. In this case, the pattern may be formed through a photolithography method or a method using a mask.

[Hole Injection Layer]

The hole injection layer is an optional constitutional element in the organic light emitting element and has a function of accepting the holes from the anode. Usually, the holes accepted from the anode are transported to the hole transport layer or the light emitting layer.

The material that may be used for the hole injection layer is the same as those described above, and hereby the detailed description will be omitted.

Although there is no particular limitation on the film thickness of the hole injection layer, the film thickness is preferably 0.1 nm to 5 μm.

The hole injection layer may be formed of a single layer, or two or more laminated layers.

The hole injection layer may be formed through a wet film formation method or a dry film formation method.

In a case where the hole injection layer is formed through the wet film formation method, usually, a step of applying an ink composition for the organic light emitting element, and a step of drying the obtained coating film are included. In this case, there is no particular limitation on the coating method; examples thereof include an ink jet printing method, a letterpress printing method, a gravure printing method, a screen printing method, and a nozzle print printing method.

In a case where the hole injection layer is formed through the dry film formation method, the vacuum deposition method, the spin coating method, or the like may be applied.

[Hole Transport Layer]

The hole transport layer is an optional constitutional element in the organic light emitting element and has a function of efficiently transporting the holes. The hole transport layer may further have a function of preventing the hole transport. The hole transport layer usually accepts the holes from the anode or the hole injection layer, and transports the holes to the light emitting layer.

The material that may be used for the hole transport layer is the same as those described above, and hereby the detailed description will be omitted.

Although there is no particular limitation on the film thickness of the hole transport layer, the film thickness is preferably 1 nm to 5 μm, more preferably 5 nm to 1 μm, and even more preferably 10 nm to 500 nm.

The hole transport layer may be formed of a single layer, or two or more laminated layers.

The hole transport layer can be formed through a wet film formation method or a dry film formation method.

In a case where the hole transport layer is formed by the wet film formation method, usually a step of applying an ink composition for the organic light emitting element, and a step of drying the obtained coating film are included. In this case, there is no particular limitation on the coating method; examples thereof include an ink jet printing method, a letterpress printing method, a gravure printing method, a screen printing method, and a nozzle print printing method.

In a case where the hole transport layer is formed through the dry film formation method, the vacuum deposition method, the spin coating method, or the like may be applied.

[Light Emitting Layer]

The light emitting layer has a function of generating light emission using the energy generated by recombination of the holes and the electrons injected into the light emitting layer.

The materials that may be used for the light emitting layer are the same as those described above, and hereby the detailed description will be omitted.

Although there is no particular limitation on the film thickness of the light emitting layer, the film thickness is preferably 2 nm to 100 nm, and more preferably 2 nm to 20 nm.

The light emitting layer may be formed through a wet film formation method or a dry film formation method.

In a case where the light emitting layer is formed by the wet film formation method, usually, a step of applying the ink composition for the organic light emitting element, and a step of drying the obtained coating film are included. In this case, there is no particular limitation on the coating method; examples thereof include an ink jet printing method, a letterpress printing method, a gravure printing method, a screen printing method, and a nozzle print printing method.

In a case where the light emitting layer is formed through the dry film formation method, the vacuum deposition method, the spin coating method or the like may be applied.

[Electron Transport Layer]

The electron transport layer is an optional constituent element in the organic light emitting element, and has a function of efficiently transporting the electrons. The electron transport layer may further have a function of preventing the electron transport. The electron transport layer usually accepts the electrons from the cathode or the electron injection layer, and transports the electrons to the light emitting layer.

The material that may be used for the electron transport layer is the same as those described above, and hereby the detailed description will be omitted.

Although there is no particular limitation on the film thickness of the electron transport layer, the film thickness is preferably 5 nm to 5 μm, and more preferably 5 nm to 200 nm.

The electron transport layer may be formed of a single layer, or two or more laminated layers.

The electron transport layer may be formed through a wet film formation method or a dry film formation method.

In a case where the electron transport layer is formed through the wet deposition method, usually, a step of applying the ink composition for the organic light-emitting element, and a step of drying the obtained coating film are included. In this case, there is no particular limitation on the coating method, and examples thereof include an ink jet printing method, a letterpress printing method, a gravure printing method, a screen printing method, and a nozzle print printing method.

In a case where the electron transport layer is formed through the dry film formation method, the vacuum deposition method, or the spin coating method may be applied.

[Electron Injection Layer]

The electron injection layer is an optional constitutional element in the organic light emitting element, and has a function to accept the electrons from the cathode. Usually, the electrons accepted from the cathode are transported to the electron transport layer or the light emitting layer.

There is no particular limitation on the electron injection material; examples thereof include alkali metals such as lithium and calcium; metals such as strontium and aluminum; alkali metal salts such as lithium fluoride and sodium fluoride; alkali metal compounds such as 8-hydroxyquinoliolato-lithium; alkaline earth metal salts such as magnesium fluoride; and oxides such as aluminum oxide. Among these, the electron injection material is preferably an alkali metal, an alkali metal salt, or an alkali metal compound, and more preferably an alkali metal salt, or an alkali metal compound.

These electron injection materials may be used singly, or two or more thereof may be used in combination.

Although there is no particular limitation on the film thickness of the electron injection layer, the film thickness is preferably 0.1 nm to 5 μm.

The electron injection layer may be formed of a single layer, or two or more laminated layers.

The electron injection layer may be formed through a wet film formation method or a dry film formation method.

In a case where the electron injection layer is formed through the wet deposition method, usually, a step of applying the ink composition for the organic light-emitting element, and a step of drying the obtained coating film are included. In this case, there is no particular limitation on the coating method, examples thereof include an ink jet printing method, a letterpress printing method, a gravure printing method, a screen printing method, and a nozzle print printing method.

In a case where the electron injection layer is formed through the dry film formation method, the vacuum deposition method, the spin coating method, or the like may be applied.

[Cathode]

There is no particular limitation on materials that may be used for the cathode; examples thereof include lithium, sodium, magnesium, aluminum, sodium-potassium alloy, magnesium/aluminum mixture, magnesium/indium mixture, aluminum/aluminum oxide (Al₂O₃) mixture, and rare earth metals. These materials may be used singly, or two or more thereof may be used in combination.

Usually, the cathode can be formed through a method such as vapor deposition or sputtering.

Although there is no particular limitation on the film thickness of the cathode, the film thickness is preferably 10 to 1,000 nm, and more preferably 10 to 200 nm.

In one embodiment, the organic EL element includes a layer formed using the electronic material composition such that undulation of the layer to be formed can be suitably prevented. This allows the obtainable organic EL element to have high performance such as prevention of luminance unevenness or the like.

In another embodiment, the light emitting layer is formed using the electronic material composition. This enables the resulting organic EL element to exhibit high driving stability.

### EXAMPLES

Hereinafter, detailed description of the present invention will be provided with reference to Examples.

<Synthesis of Siloxane Monomers>

### Example 1

100 g of SILAPLANE FM-0411 (manufactured by JNC Corporation) and 16.8 g of potassium tert-butoxide were charged into a 500 mL three-necked flask, which was purged with argon gas and into which 100 g of tetrahydrofuran (THF) was inserted, and the mixture was stirred at room temperature for an hour. 11.8 g of 5-bromo-1,3-pentadiene was added dropwise thereto, and the mixture was stirred at room temperature for 18 hours. Thereafter, THF was distilled off under reduced pressure, and the mixture was extracted with toluene, and the obtained product was washed three times with water, and then dried over sodium sulfate. Thereafter, the mixture was purified through silica gel column chromatography so as to obtain Siloxane monomer a of the present invention. The yield was 18 g.

The structure of Siloxane monomer a is shown below.

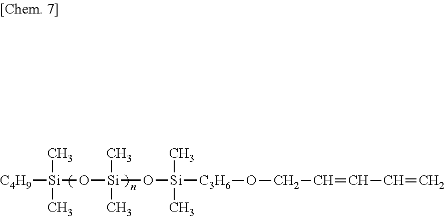

### Example 2

In the same manner as in Example 1 except that 12.2 g of 4-(chloromethyl)styrene was used instead of 5-bromo-1,3-pentadiene, Siloxane monomer b of the present invention was synthesized. The yield was 12 g.

The structure of Siloxane monomer b is shown below.

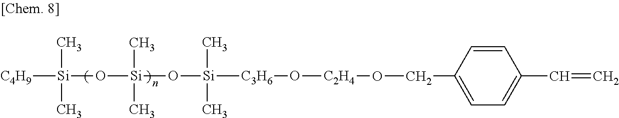

<Synthesis of Polymer>

### Example 3

700 mg of styrene, 672 mg of Siloxane monomer a obtained in Example 1, 27.6 mg of PERBUTYL Z (manufactured by NOF Corporation), and 3.3 g of cyclohexanone were placed in a 10 mL three-necked flask and stirred at 110° C. for 30 hours under nitrogen gas charging. The obtained reaction solution was added dropwise to methanol to precipitate the polymer, and after filtration and drying, 1.3 g of Polymer A of the present invention was obtained.

The number-average molecular weight (Mn) and the weight-average molecular weight (Mw) of the obtained Polymer A were measured and found to be 7,900 and 20,000, respectively. The number-average molecular weight and the weight-average molecular weight were measured using polystyrene as the standard substance using a high-speed GPC apparatus (manufactured by Tosoh Corporation).

### Example 4

In the same manner as in Example 3 except that Siloxane monomer b obtained in Example 2 was used in place of Siloxane monomer a, Polymer B of the present invention was synthesized.

The number-average molecular weight (Mn) and the weight-average molecular weight (Mw) of the obtained Polymer B were measured and found to be 8,100 and 21,000, respectively.

### Example 5

In the same manner as in Example 4 except that benzyl vinyl ether was used instead of the styrene, Polymer C of the present invention was synthesized.

The number-average molecular weight (Mn) and the weight-average molecular weight (Mw) of the obtained Polymer C were measured and found to be 8,500 and 22,000, respectively.

### Synthesis Example 1

In the same manner as in Example 3 except that FM-0711 was used instead of Siloxane monomer A, Polymer D was synthesized.

The number-average molecular weight (Mn) and the weight-average molecular weight (Mw) of the obtained Polymer D were measured and found to be 9,500 and 24,000, respectively.

The structure of FM-0711 is shown below.

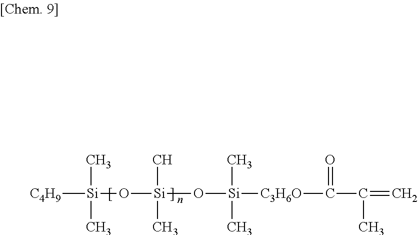

<Synthesis of Host Material>

### [Synthesis Example 2] Synthesis of Intermediate 1

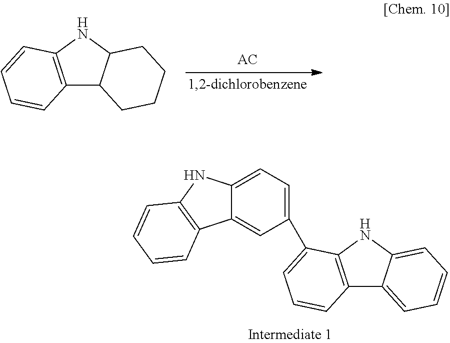 [SMILES: c1ccc2c(c1)NC1CCCCC21 ; c1ccc2c(c1)[nH]c1ccc(-c3cccc4c3[nH]c3ccccc34)cc12]

1,2,3,4-tetrahydrocarbazole(12 g, 72 mmol), activated carbon (12 g) and 120 mL of 1,2-dichlorobenzene were sequentially added to a 250 mL four-necked flask, and while air was blown into at the rate of 500 mL/min, the reaction mixture was stirred at 150° C. for 15 hours. After cooling the reaction solution to room temperature, the reaction solution was filtered, the organic solvent was removed under reduced pressure, and purified by column chromatography. After removing the organic solvent under reduced pressure, 3.2 g (yield: 10%) of a yellow solid (Intermediate 1) was obtained.

### [Synthesis Example 3] Synthesis of 9,9′-(p-tert-butylphenyl)-1,3-biscarbazole

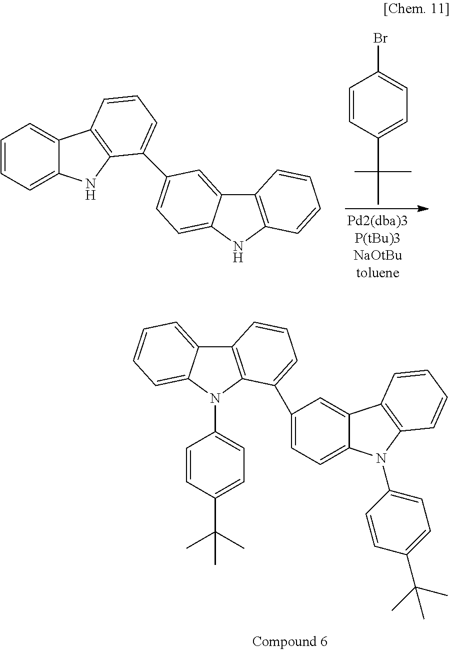

Under an argon atmosphere, Intermediate 1 (0.836 g, 2.52 mmol), 1-bromo-4-t-butylbenzene(1.287 g, 6.04 mmol), tris(dibenzylidene)dipalladium(0.130 g, 0.13 mmol), tri-t-butylphosphine(0.076 g, 0.38 mmol), sodium-t-butoxide (0.725 g, 7.55 mmol) and 50 mL of toluene were sequentially added into a 200 mL three-necked flask, and the mixture was heated under reflux for 8 hours. After cooling the reaction solution to room temperature, water was added and an organic layer was recovered with a separating funnel. The organic solvent was removed under reduced pressure and purified by silica gel chromatography, whereby 0.9 g (yield 60%) of a white solid (Compound 6) is obtained.

<Preparation of Electronic Material Composition>

Polymers A to C of the present invention obtained in Examples 3 to 5 and Polymer D obtained in Synthesis Example 1 were used to prepare electronic material compositions including a light emitting material as an organic EL material.

### Example 6

0.001 g of Polymer A synthesized in Example 3 was dissolved in 9.9 g of tetralin, which is the solvent. Into the obtained solution, 0.04 g of tris[2-(p-tolyl)pyridine]iridium (Ir (mppy)₃) (manufactured by Lumtec) and 0.26 g of 9,9′-(p-tert-butylphenyl)-1,3-biscarbazole synthesized in Synthesis Example 3 were added and heated at 60° C. to prepare an electronic material composition.

### Example 7

An electronic material composition was prepared in the same manner as in Example 6 except that Polymer A was replaced with Polymer B synthesized in Example 4.

### Example 8

An electronic material composition was prepared in the same manner as in Example 6 except that Polymer A was replaced with Polymer C synthesized in Example 5.

### Comparative Example

An electronic material composition was prepared in the same manner as in Example 6 except that Polymer A was replaced with Polymer D obtained in Synthesis Example 1.

<Evaluation>

The following various evaluations were made on the electronic material compositions prepared in Examples 6 to 8 and Comparative Example.

[Evaluation of Smoothness]

0.1 μL of the electronic material composition was added dropwise onto an indium tin oxide (ITO) substrate and dried under reduced pressure of 1 Torr at 25° C. The difference between a convex portion and a concave portion (unevenness difference) of the obtained organic thin film was measured using a light interference surface shape measurement apparatus (manufactured by Ryoka Systems Inc.), and was evaluated according to following criteria. The convex portion means the highest surface of the organic thin film surface with respect to the horizontal plane, and the concave portion means the lowest surface of the organic thin film surface with respect to the horizontal plane.

[Evaluation of Luminous Efficiency]

Organic EL elements were produced to evaluate the luminous efficiency of the obtained organic light emitting element.

The organic EL elements were produced as follows.

That is, a cleansed ITO substrate was irradiated with UV/O₃, a film of poly(3,4-ethylenedioxythiophene)-poly(styrenesulfonic acid) (PEDOT-PSS) was formed thereon to provide a thickness of 45 nm by spin coating, and heated at 180° C. for 15 minutes in the air so as to form a hole injection layer. Subsequently, a film of 0.3 wt % xylene solution of HT-2 represented by the following formula was formed to provide a thickness of 10 nm on the hole injection layer by spin coating and dried at 200° C. for 30 minutes in a nitrogen atmosphere so as to form a hole transport layer. Next, a film of each of the electronic material compositions obtained in Examples 6 to 8 and Comparative Example was formed on the hole transport layer to provide a thickness of 30 nm by spin coating, dried at 25° C. under reduced pressure of 1 Torr for 3 minutes, and then dried at 110° C. for 15 minutes in a nitrogen atmosphere so as to form a light emitting layer. Under the vacuum condition of 5×10⁻³ Pa, a film of ET-1 represented by the following formula was formed to provide a thickness of 45 nm as an electron transport layer, a film of lithium fluoride was formed to provide a thickness of 0.5 nm as an electron injection layer, and a film of aluminum was formed to provide a thickness of 100 nm as a cathode, subsequently. Finally, the substrate was delivered to a glove box and sealed with a glass substrate, whereby an organic light emitting element was obtained.

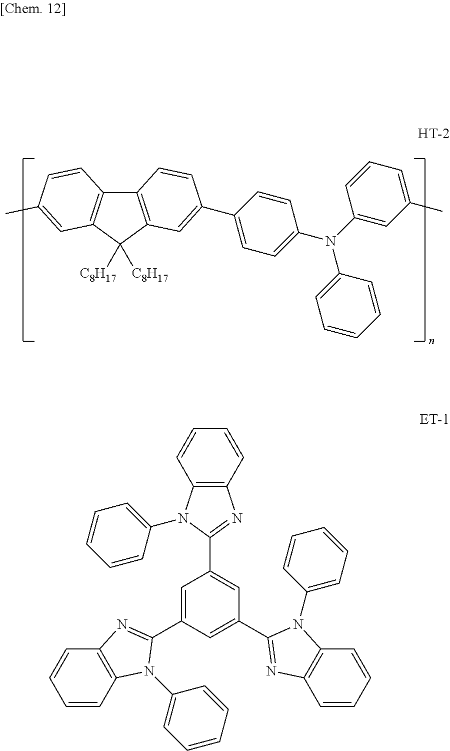

[Luminous Efficiency]

Using the produced organic EL element, a luminous efficiency was evaluated.

More specifically, the produced organic EL element was connected to an external power source and light emission from the organic EL element was measured with BM-9 (manufactured by TOPCON Corporation). At this time, the luminous efficiency was calculated at the current value of 10 mA/cm².

### [Lifetime]

Lifetime was evaluated using the produced organic EL element.

More specifically, current of 10 mA/cm² was applied to the produced organic EL element, and the luminance half-life was measured with a photodiode type lifetime measurement apparatus (manufactured by System Engineers Co., Ltd.).

The obtained results are shown in Table 1 below.

TABLE 1

| | | | Unevenness | Luminous | Life- |
|---|---|---|---|---|---|
| | Siloxane | Hydrophobic | difference | efficiency | time |
| | monomer | monomer | (nm) | (%) | (%) |
| Comparative | FM-0711 | Styrene | 85 | 100 | 100 |
| Example | | | | | |
| Example 6 | a | Styrene | 47 | 115 | 171 |
| Example 7 | b | Styrene | 22 | 129 | 182 |
| Example 8 | b | Benzyl vinyl | 31 | 119 | 165 |
| | | ether | | | |

As is apparent from the results in Table 1, in comparison with Comparative Example, in a case where a coating film was formed by using the electronic material compositions of Examples 6 to 8, films with small unevenness difference were obtained, and lifetimes of the elements obtained using them were also increased. That is, it has been found that the use of the electronic material composition of the present invention improves the smoothness of the coating film to be obtained and allows the element to exhibit excellent driving stability.

1. Monomers represented by general formula (1): 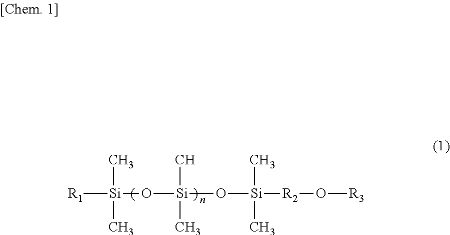
wherein n represents 1 to 1,000, R₁ and R₂ represent a hydrocarbon group which may include an ether bond, and R₃ represents a vinyl group or an organic group having a vinyl group, provided that the organic group does not include a carbonyl group in a structure thereof.

2. A polymer obtained by polymerizing at least a monomer selected from the monomers represented by the general formula (1).

3. A polymer obtained by copolymerizing at least a monomer selected from the monomers represented by general formula (1) and a monomer other than the monomers represented by the general formula (1).

4. A composition comprising the polymer according to claim 2.

5. An electronic material composition comprising the polymer according to claim 2.

6. An electronic element comprising the composition according to claim 4.

7. A composition comprising the polymer according to claim 3.

8. An electronic material composition comprising the polymer according to claim 3.

9. An electronic element comprising the electronic material composition according to claim 5.
